(19) United States
(12) Patent Application Publication
(10) Pub. No.: US 2026/0186429 A1
(43) Pub. Date: Jul. 2, 2026

(54) IN-SITU CLEANING FOR LITHOGRAPHIC APPARATUS

(71) Applicant: ASML Netherlands B.V., Veldhoven (NL)

(72) Inventors: Max KOOLE, Eindhoven (NL); Andrey NIKIPELOV, Eindhoven (NL); Vladimir KVON, Eindhoven (NL)

(73) Assignee: ASML Netherlands B.V., Veldhoven (NL)

(21) Appl. No.: 19/131,115

(22) PCT Filed: Dec. 15, 2023
(86) PCT No.: PCT/EP2023/086000

§ 371 Date: May 19, 2025

(30) Foreign Application Priority Data
Dec. 23, 2022 (EP) 2216490.7

(51) Int. Cl. G03F 7/00; B08B 7/00

(52) U.S. Cl. CPC G03F 7/70925; B08B 7/0057

(57) ABSTRACT

A photoelectric plate (300) for use in place of a patterning device in a lithographic apparatus, the photoelectric plate comprising: a base layer (301); and a coating (302) provided on the base layer; wherein the coating is configured to convert impinging photons of EUV radiation into free electrons at a higher conversion efficiency than the base layer.

### CROSS-REFERENCE TO RELATED APPLICATIONS

This application claims priority of EP Application Serial No. 22216490.7 which was filed on 23 Dec. 2023 and which is incorporated herein in its entirety by reference.

### FIELD

The present invention relates to lithographic apparatuses, particularly extreme ultraviolet (EUV) lithographic apparatuses.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$C D = {k}_{1} ⋆ \frac{λ}{N A} \qquad ( 1 )$$

where λ is the wavelength of the radiation used, NA is the numerical aperture of the projection system used to print the pattern, k₁ is a process-dependent adjustment factor, also called the Rayleigh constant, and CD is the feature size (or critical dimension) of the printed feature. It follows from Equation (1) that reduction of the minimum printable size of features can be obtained in three ways: by shortening the exposure wavelength λ, by increasing the numerical aperture NA or by decreasing the value of k₁.

In order to shorten the exposure wavelength and, thus, reduce the minimum printable size, it has been proposed to use an extreme ultraviolet (EUV) radiation source. EUV radiation is electromagnetic radiation having a wavelength within the range of 10-20 nm, for example within the range of 13-14 nm. It has further been proposed that EUV radiation with a wavelength of less than 10 nm could be used, for example within the range of 5-10 nm such as 6.7 nm or 6.8 nm. Such radiation is termed extreme ultraviolet radiation or soft x-ray radiation. Possible sources include, for example, laser-produced plasma sources, discharge plasma sources, or sources based on synchrotron radiation provided by an electron storage ring, or a free electron laser.

Once the EUV radiation has been generated, it is directed through the lithographic apparatus by a plurality of mirrors to a patterning surface of the patterning device, which imparts the desired pattern to the EUV radiation.

Contaminant particles may be present in the environment surrounding the patterning device. Contaminant particles from various sources may be produced during the operation of the lithographic apparatus. Contaminant particles may also be introduced during manufacturing of components of the apparatus, and/or during assembly of the apparatus. Some of the contaminant particles may be present on non-critical surfaces of the apparatus.

EUV radiation propagates in low pressure gas, filling the lithographic apparatus, for example hydrogen. Photo-ionization of such gas, and photoelectric effect from EUV illuminated surfaces, for example the patterning device, generates energetic electrons (up to 100 eV) and ions, which together are referred to as EUV-induced plasma. As found by the present inventors, the EUV-induced plasma may come into contact with the contaminant particles present on non-critical surfaces of the apparatus, and release them into the patterning environment. As a result, some of the released contaminant particles may be transferred onto the reticle, which in turn causes imaging defects in the patterning of the substrate.

At present, non-critical surfaces of the apparatus are cleaned after maintenance actions by flushing the patterning environment with a flow of gas. However, this method of cleaning requires putting the lithographic apparatus out of the ready-for-exposure state for an extended period of time, which results in a significant cost in terms of productive availability.

It is further found by the present inventors that, after flushing, defects in the patterning are still present, which suggests that the flushing method does not adequately remove contaminant particles that may become released during a patterning operation.

### SUMMARY OF THE INVENTION

An aim of the present invention is thus to provide a more effective technique of cleaning an EUV lithographic apparatus.

Another aim of the present invention is to reduce the availability cost associated with cleaning operations of an EUV lithographic apparatus.

According to an aspect of the present invention, there is provided a photoelectric plate for use in place of a patterning device in a lithographic apparatus, the photoelectric plate comprising:
a base layer; and
a coating provided on the base layer;
wherein the coating is configured to convert impinging photons of EUV radiation into free electrons at a higher conversion efficiency than the base layer.

According to another aspect of the present invention, there is provided a method comprising:
placing the photoelectric plate described above in a patterning device support structure of a lithographic apparatus; and
directing EUV radiation onto the photoelectric plate.

### BRIEF DESCRIPTION OF THE DRAWINGS

Embodiments of the invention will now be described, by way of example only, with reference to the accompanying schematic drawings, in which corresponding reference symbols indicate corresponding parts.

FIG. 1 schematically depicts a lithographic apparatus.

FIG. 2 schematically depicts a more detailed view of the lithographic apparatus.

FIG. 3 schematically depicts a patterning device whilst being exposed to EUV radiation.

FIG. 4 schematically depicts an embodiment of a photoelectric plate for converting EUV photons into an electron flux.

FIG. 5 illustrates the principal direction of emission of an electron produced by the photoelectric effect.

FIG. 6 schematically depicts an embodiment of the photoelectric plate with a rough surface.

FIG. 7 schematically depicts an embodiment of the photoelectric plate with grooves.

FIG. 8 schematically depicts an embodiment of the photoelectric plate with a negative voltage bias.

FIG. 9 illustrates the effect of the angle of incidence of a photon on the generation of electrons.

FIG. 10 schematically depicts using the generated electrons to remove contaminant particles.

FIG. 11 depicts an example operating cycle of a lithographic apparatus.

The features shown in the Figures are not necessarily to scale, and the size and/or arrangement depicted is not limiting. It will be understood that the Figures include optional features which may not be essential to the invention. Furthermore, not all of the features of the apparatus are depicted in each of the figures, and the Figures may only show some of the components relevant for describing a particular feature.

### DETAILED DESCRIPTION

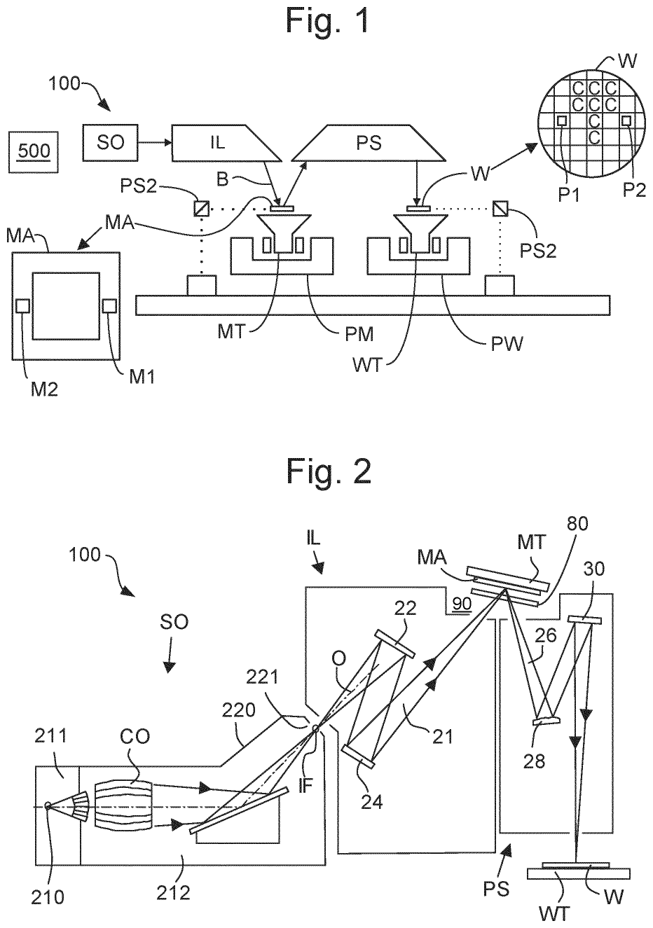

FIG. 1 schematically depicts a lithographic apparatus 100 including a source collector module SO according to one embodiment of the invention. The apparatus 100 comprises:
an illumination system (or illuminator) IL configured to condition a radiation beam B (e.g., EUV radiation).
a support structure (e.g., a mask table) MT constructed to support a patterning device (e.g., a mask or a reticle) MA and connected to a first positioner PM configured to accurately position the patterning device;
a substrate table (e.g., a wafer table) WT constructed to hold a substrate (e.g., a resist-coated wafer) W and connected to a second positioner PW configured to accurately position the substrate; and
a projection system (e.g., a reflective projection system) PS configured to project a pattern imparted to the radiation beam B by patterning device MA onto a target portion C (e.g., comprising one or more dies) of the substrate W.

The illumination system IL may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure MT can use mechanical, vacuum, electrostatic or other clamping techniques to hold the patterning device MA. The support structure MT may be a frame or a table, for example, which may be fixed or movable as required. The support structure MT may ensure that the patterning device MA is at a desired position, for example with respect to the projection system PS.

The term “patterning device” should be broadly interpreted as referring to any device that can be used to impart a radiation beam B with a pattern in its cross-section such as to create a pattern in a target portion C of the substrate W. The pattern imparted to the radiation beam B may correspond to a particular functional layer in a device being created in the target portion C, such as an integrated circuit.

Examples of patterning devices include masks, programmable mirror arrays, and programmable liquid-crystal display (LCD) panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam, which is reflected by the mirror matrix.

The projection system PS, like the illumination system IL, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the lithographic apparatus 100 is of a reflective type (e.g., employing a reflective mask).

The lithographic apparatus 100 may be of a type having two (dual stage) or more substrate tables WT (and/or two or more support structures MT). In such a “multiple stage” lithographic apparatus the additional substrate tables WT (and/or the additional support structures MT) may be used in parallel, or preparatory steps may be carried out on one or more substrate tables WT (and/or one or more support structures MT) while one or more other substrate tables WT (and/or one or more other support structures MT) are being used for exposure.

Referring to FIG. 1, the illumination system IL receives an extreme ultraviolet radiation beam from the source collector module SO. Methods to produce EUV light include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet, stream or cluster of material having the required line-emitting element, with a laser beam. The source collector module SO may be part of an EUV radiation system including a laser, not shown in FIG. 1, for providing the laser beam exciting the fuel. The resulting plasma emits output radiation, e.g., EUV radiation, which is collected using a radiation collector, disposed in the source collector module. The laser and the source collector module SO may be separate entities, for example when a CO₂ laser is used to provide the laser beam for fuel excitation.

In such cases, the laser is not considered to form part of the lithographic apparatus 100 and the radiation beam B is passed from the laser to the source collector module SO with the aid of a beam delivery system comprising, for example, suitable directing mirrors and/or a beam expander. In other cases the source may be an integral part of the source collector module SO, for example when the source is a discharge produced plasma EUV generator, often termed as a DPP source.

The illumination system IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illumination system IL can be adjusted. In addition, the illumination system IL may comprise various other components, such as facetted field and pupil mirror devices. The illumination system IL may be used to condition the radiation beam B, to have a desired uniformity and intensity distribution in its cross-section.

The radiation beam B is incident on the patterning device (e.g., mask) MA, which is held on the support structure (e.g., mask table) MT, and is patterned by the patterning device MA. After being reflected from the patterning device (e.g., mask) MA, the radiation beam B passes through the projection system PS, which focuses the radiation beam B onto a target portion C of the substrate W. With the aid of the second positioner PW and position sensor PS2 (e.g., an interferometric device, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g., mask) MA with respect to the path of the radiation beam B. The patterning device (e.g., mask) MA and the substrate W may be aligned using mask alignment marks M1, M2 and substrate alignment marks P1, P2.

A controller 500 controls the overall operations of the lithographic apparatus 100 and in particular performs an operation process described further below. Controller 500 can be embodied as a suitably-programmed general purpose computer comprising a central processing unit, volatile and non-volatile storage means, one or more input and output devices such as a keyboard and screen, one or more network connections and one or more interfaces to the various parts of the lithographic apparatus 100. It will be appreciated that a one-to-one relationship between controlling computer and lithographic apparatus 100 is not necessary. In an embodiment of the invention one computer can control multiple lithographic apparatuses 100. In an embodiment of the invention, multiple networked computers can be used to control one lithographic apparatus 100. The controller 500 may also be configured to control one or more associated process devices and substrate handling devices in a lithocell or cluster of which the lithographic apparatus 100 forms a part. The controller 500 can also be configured to be subordinate to a supervisory control system of a lithocell or cluster and/or an overall control system of a fab.

FIG. 2 shows the lithographic apparatus 100 in more detail, including the source collector module SO, the illumination system IL, and the projection system PS. An EUV radiation emitting plasma 210 may be formed by a plasma source. EUV radiation may be produced by a gas or vapor, for example Xe gas, Li vapor or Sn vapor in which the radiation emitting plasma 210 is created to emit radiation in the EUV range of the electromagnetic spectrum. In an embodiment, a plasma of excited tin (Sn) is provided to produce EUV radiation.

The radiation emitted by the radiation emitting plasma 210 is passed from a source chamber 211 into a collector chamber 212.

The collector chamber 212 may include a radiation collector CO. Radiation that traverses the radiation collector CO can be focused in a virtual source point IF. The virtual source point IF is commonly referred to as the intermediate focus, and the source collector module SO is arranged such that the virtual source point IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the unpatterned beam 21, at the patterning device MA, as well as a desired uniformity of radiation intensity at the patterning device MA. Upon reflection of the unpatterned beam 21 at the patterning device MA, held by the support structure MT, a patterned beam 26 is formed and the patterned beam 26 is imaged by the projection system PS via reflective elements 28, 30 onto a substrate W held by the substrate table WT. Masking blades 80 having a controllable opening which lets EUV radiation pass through may also be used to protect the patterning device from contaminants.

More elements than shown may generally be present in the illumination system IL and the projection system PS. Further, there may be more mirrors present than those shown in the Figures, for example there may be 1-6 additional reflective elements present in the projection system PS than shown in FIG. 2.

Alternatively, the source collector module SO may be part of an LPP radiation system.

As depicted in FIG. 1, in an embodiment the lithographic apparatus 100 comprises an illumination system IL and a projection system PS. The illumination system IL is configured to emit a radiation beam B. The projection system PS is separated from the substrate table WT by an intervening space. The projection system PS is configured to project a pattern imparted to the radiation beam B onto the substrate W. The pattern is for EUV radiation of the radiation beam B.

The space intervening between the projection system PS and the substrate table WT can be at least partially evacuated. The intervening space may be delimited at the location of the projection system PS by a solid surface from which the employed radiation is directed toward the substrate table WT.

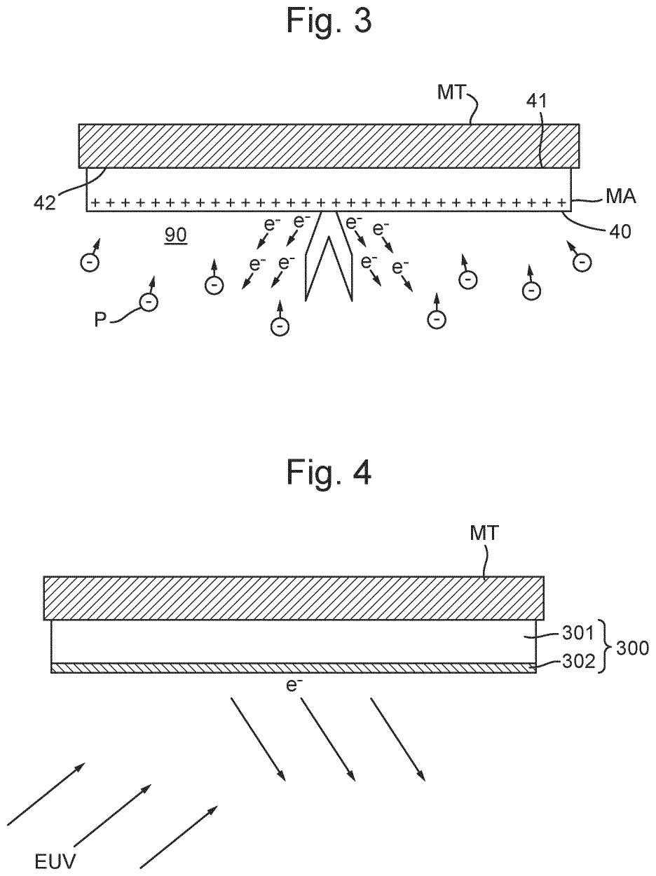

FIG. 3 depicts a schematic representation of a patterning device MA clamped to a support structure MT. As described above, the support structure MT may use mechanical, vacuum, electrostatic or other clamping techniques to hold the patterning device MA. The support structure MT may comprise a plurality of burls (cone-shaped protrusions) on a supporting surface 42 of the support structure MT that faces a non-patterning surface 41 of the patterning device MA. When the patterning device MA is clamped to the support structure MT, the non-patterning surface 41 is in contact with distal ends of the plurality of burls. It is not necessary for each of the plurality of burls to be in contact with the non-patterning surface 41. These burls are not shown in FIG. 3.

Both the patterning device MA and support structure MT may be contained within a patterning device environment 90. The patterning device environment 90 may be separated from an external environment surrounding the lithographic apparatus 100 and/or other components within the lithographic apparatus such that gases and contaminant particles P are substantially prevented from entering the patterning device environment 90.

The patterning device environment 90 may be partially evacuated of gas. That is, the pressure within the patterning device environment 90 may be less than ambient pressure. This is to limit the attenuation of EUV radiation as it travels through the patterning device environment 90. Even though the pressure within the patterning device 90 is less than ambient pressure, it is not a perfect vacuum, so gas particles are present in the patterning device environment 90.

Contaminant particles P may also be present in the patterning device environment 90. Despite the separation of the patterning device environment 90 from the external environment and/or other components within the lithographic apparatus, it is possible that some contaminant particles P may enter the patterning device environment 90 from these locations. Also, contaminant particles P may be generated within the patterning device environment 90 by mechanisms such as abrasive wear, which occurs when there is relative motion between contacting surfaces. Contaminant particles from various sources may be produced during the operation of the lithographic apparatus. Contaminant particles may also be introduced during manufacturing of components of the apparatus, and/or during assembly of the apparatus.

During EUV lithography, the EUV radiation within the patterning device environment 90 causes contaminant particles P to become negatively charged. This occurs as a result of at least two main mechanisms. A first mechanism is a result of the formation of plasma from the gas molecules within the patterning device environment 90, which are excited by the EUV radiation. Free electrons within the plasma may be absorbed by the contaminant particles P, resulting in those particles becoming negatively charged and, thus, released from surfaces of the lithographic apparatus. A second mechanism is a consequence of the photoelectric effect which causes the patterning surface 40 to become positively charged. Specifically, electrons that have been ejected from the patterning surface 40 as a result of the photoelectric effect may be absorbed by the contaminant particles P, causing them to become negatively charged, and thus released.

As a result of the patterning surface 40 becoming positively charged and the contaminant particles P becoming negatively charged, an attractive electrostatic force is exerted between the patterning surface 40 and the contaminant particles P. This causes the contaminant particles P to accelerate towards the patterning surface 40. Consequently, it is likely that contaminant particles within the lithographic apparatus will be deposited onto the patterning surface 40, thereby causing imaging defects.

As noted above, at present, non-critical surfaces of the apparatus are cleaned after maintenance actions by flushing the patterning device environment 90 with a flow of gas. However, this method of cleaning requires putting the lithographic apparatus out of the ready-for-exposure state for an extended period of time, which results in a significant cost in terms of productive availability.

It is further found by the present inventors that, after flushing, defects in the patterning are still present, which suggests that the flushing method does not adequately remove contaminant particles that may become released during a patterning operation.

With reference to FIG. 4, the basic idea of the present invention is to provide a photoelectric plate 300 for use in place of the patterning device MA in the lithographic apparatus. The photoelectric plate may be thought of as a “dummy” reticle. Unlike the patterning device MA, however, the purpose of the photoelectric plate 300 is not to impart a pattern onto a wafer substrate. Instead, the purpose of the photoelectric plate 300 is to receive EUV radiation and convert it into a flux of electrons by means of the photoelectric effect. The photoelectric plate 300 may be used during a cleaning operation, prior to which the patterning device MA has been swapped out for the photoelectric plate. When the photoelectric plate 300 is installed, EUV radiation may be directed onto the photoelectric plate in a similar way that EUV radiation is directed to the patterning device MA during a lithography process. Unlike a patterning device MA, the photoelectric plate 300 is not required to reflect EUV radiation. Instead, EUV radiation is absorbed and converted into a flux of electrons. In the same way that EUV-induced plasma may release contaminant particles from surfaces of the lithographic apparatus 100 during a lithography process, the free electrons generated during the cleaning operation may similarly release contaminant particles. The released contaminant particles may then be removed from the patterning device environment 90 during the cleaning operation. As a result, the amount of contaminant particles remaining may be reduced, and thus fewer contaminant particles are likely to be released during a lithography process.

FIG. 4 schematically depicts an embodiment of the photoelectric plate 300. As shown, the photoelectric plate 300 comprises a base layer 301 and a coating 302 provided on the base layer 301. As shown in FIG. 4, EUV radiation may be directed at the photoelectric plate 300. The EUV radiation may impinge on the coating 302. The base layer may comprise a low expansion ceramic or glass. The base layer may include a conductive coating that enables electrostatic clamping.

The coating 302 is configured to convert impinging photons of EUV radiation into electrons at a higher conversion efficiency than the base layer 301 or at a higher conversion efficiency than a patterning device. That is, for each impinging photon of EUV radiation, the coating 302 produces, on average, a greater number of electrons than the base layer 301 would if an EUV photon were to impinge on it. Therefore, to the extent that any arbitrary material exhibits the photoelectric effect to some degree, the coating 302 is differentiated from the base layer 301 at least in that the coating 302 exhibits a greater degree of the photoelectric effect. As a result, compared with the base layer 301 on its own, the provision of the coating 302 may provide enhanced photoelectric conversion of EUV photons into free electrons.

Although the electrons shown in FIG. 4 appear to be travelling in a particular direction, this is for illustrative purposes only. The direction of travel of the free electrons may be other than as shown in FIG. 4.

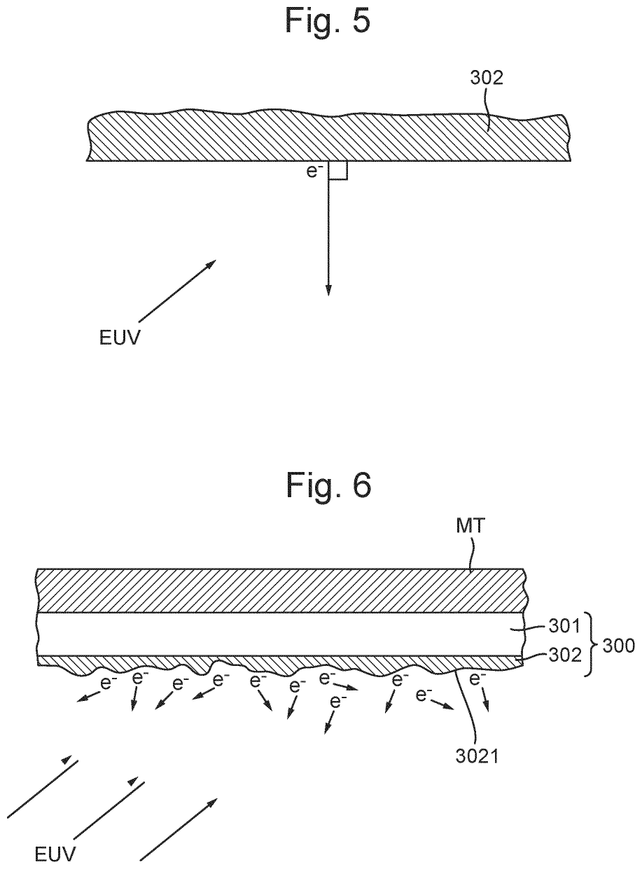

Referring to FIG. 5, when the coating 302 is exposed to EUV radiation, the free electrons tend to be emitted in a principal direction which is perpendicular to the surface of the coating 302. More specifically, when an EUV photon reaches some distance into the surface of the coating 302 and encounters an orbital electron of an atom of the coating material, the orbital electron may be released as a primary electron. In general, the direction of travel of the primary electron will be perpendicular to that of the photon which released it. Therefore, in the scenario shown in FIG. 5, where the EUV photon arrives at an angle to the coating 302, the primary electron will initially travel in a direction perpendicular to the EUV photon. However, the direction of travel of the primary photon is not the direction of emission of the electron flux. This is because, in the majority of cases, the primary electron does not leave the coating material; instead, it encounters another atom of the coating material, and causes one or more secondary electrons to be released.

The one or more secondary electrons may also encounter further atoms of the coating material and cause the generation of further secondary electrons. Starting from a single impinging EUV photon, the process of secondary electron generation may result in the release of a large number of electrons. A fraction of these secondary electrons will recombine with the atoms of the coating material, while the remainder of these secondary electrons will escape the surface of the coating 302 and be emitted as a flux of free electrons. Because the emitted electrons are likely to have undergone several generations of secondary electron emission, their directions of travel are no longer correlated to the angle of incidence of the EUV photon. Instead, the direction of the electron flux will be statistically determined by the orientation of the local surface of the coating 302. Specifically, the direction of the electron flux will be perpendicular to the local surface of the coating 302. This is because the most energetic (and thus fastest) electrons are statistically most likely to be emitted in the direction perpendicular to the local surface of the coating 302.

Therefore, if the coating 302 of the photoelectric plate 300 has a very smooth surface, then electron flux produced by the coating 302 will travel in an average direction perpendicular to the surface of the coating 302.

However, it may not always be desirable to direct the electrons in the direction perpendicular to the base layer 301 of the photoelectric plate 300. Specifically, a very smooth coating 302 may not direct electrons to a location within the lithographic apparatus 100 where the electrons are most needed for accelerated release of particles from non-critical surfaces. For example, contamination particles may not be present at the highest concentration at a location of the lithographic apparatus 90 directly facing the photoelectric plate 300. Contaminant particles may be present in other parts of the lithographic apparatus 100. Indeed, contaminant particles may be spread over various surfaces within the lithographic apparatus 100, particularly surfaces surrounding the patterning device environment 90.

Therefore, it may be desirable to direct the free electrons in directions other than the direction perpendicular to the base layer 301 of the photoelectric plate 300. FIG. 6 shows another embodiment of the photoelectric plate 300. As shown, the coating 302 may be formed with a rough surface 3021. Due to the roughness of the surface 3021, the local surface at different portions of the coating 302 may have a local normal pointing in a wide range of directions. As a result, because the free electrons are, on average, emitted in the direction of the local normal, the rough surface 3021 of the photoelectric plate 300 of FIG. 6 may cause the free electrons to be emitted in a wide variety of directions. In other words, the roughness of the surface 3021 may cause the free electrons to be emitted as a diffuse electron flux. Because the electron flux is diffuse, the free electrons may be able to reach different surfaces within the lithographic apparatus 100.

In order for the electrons to be directed in different directions, the rough surface 3021 of the coating 302 may comprise surface features of different orientations. For example, the rough surface 3021 of the coating 302 may comprise surface features having a dimension of at least 1 μm. Depending on the material of the coating 302, a variety of techniques may be used to roughen the surface of the coating 302. For example, the surface of the coating 302 may be roughened by grinding or sandblasting. Alternatively, a base layer 301 may be roughened on the side facing EUV prior to application of a conformal layer as coating 302. Lateral and vertical dimensions of rough features may have comparable sizes to increase angular spread in the free electrons.

In the embodiment shown in FIG. 6, the free electrons may be emitted randomly within a range of directions. However in certain scenarios, it may not always be desirable to direct electrons randomly within the lithographic apparatus 100. For example, it may be that certain surfaces within the lithographic apparatus 90 are known to be particularly prone to accumulate and release contaminant particles when exposed to EUV-induced plasma. In such scenarios, it may be desirable to direct a greater proportion, or even substantially all, of the free electrons towards a particular surface within the lithographic apparatus 100. In other words, it may be desirable to have control over the direction of the electron flux generated by the coating 302.

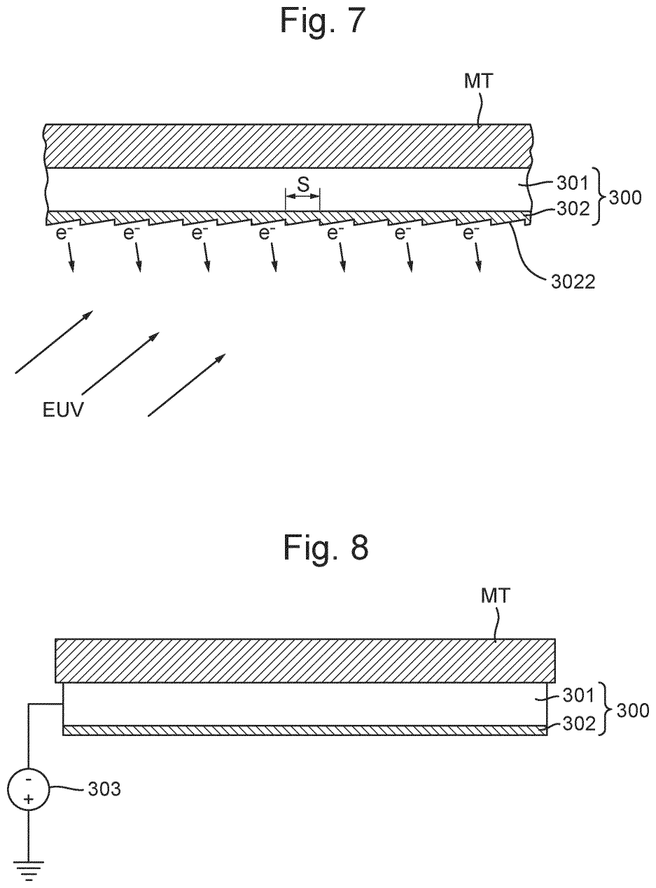

FIG. 7 shows an embodiment of the photoelectric plate 300 which may provide directional control of the electron flux. As shown, the coating 302 may be formed with a plurality of grooves. In particular, the grooves may be, in part, formed by a plurality of surface segments 3022. As noted above, the aggregate direction of emission of the free electrons is predominantly determined by the orientation of the local surface. Therefore, the surface segments 3022 of the coating 302 may be angled at an orientation in order to direct the electrons in the required direction. In particular, the surface segments 3022 of the coating 302 may be non-parallel to the base layer 301 of the photoelectric plate 300. As a result, the free electrons, on average, will be directed in the direction perpendicular to the surface segments 3022, rather than in the direction perpendicular to the base layer 301 (as in the case where the coating 302 is very smooth). For example, the surface segments 3022 may be angled at about 25°, 30°, 35°, 40°, 45° or 50° to the base layer 301.

The geometry of the grooves of the coating 302 may be chosen as desired, as long as they provide adequate surface segments 3022 angled at the orientation needed to direct the free electrons in the required direction. Furthermore, although FIG. 7 shows only one set of grooves providing surface segments 3022 facing a common direction, the coating 302 may be provided with several sets of grooves, each set providing a plurality of surface segments 3022 facing a different direction. For example, the coating 302 may be divided into several parts in which different sets of grooves are formed. For example, a photoelectric plate may have a first part that preferentially directs electrons towards a first surface of the lithographic apparatus 100 and a second part that preferentially directs electrons towards a second surface of the lithographic apparatus 100. By providing several sets of grooves, it is possible to direct the free electrons in several directions using the same photoelectric plate 300 as required. It may possible to direct the free electrons in several directions simultaneously. This may enable several areas of the lithographic apparatus 100 to be cleaned simultaneously. Alternatively, by directing EUV radiation to only a portion of the photoelectric plate 300 at a time, free electrons may be directed in different directions selectively or sequentially as required.

As with the embodiment shown in FIG. 6, the grooves in the embodiment shown in FIG. 7 may have a dimension greater than the wavelength of the EUV radiation. In particular, the grooves may have a width s. The width s of the grooves may also define the spatial periodicity of the grooves. For example, the grooves may have a width s of at least 1 μm.

A variety of manufacturing techniques may be used to form the grooves on the coating 302. For example, the grooves may be formed by machining, ion beam profiling, lithography, stamping, or imprint lithography. Other suitable manufacturing techniques may be used.

As noted above, in theory, any material will exhibit some degree of the photoelectric effect in EUV (that exceeds photoelectric threshold for any material). However, certain materials exhibit a greater degree of the photoelectric effect. Furthermore, for a given material, the degree of photoelectric effect may also depend on the wavelength of the impinging photon. Therefore, in order to generate an adequate amount of electrons for the purpose of cleaning surfaces within the lithographic apparatus 90, the coating 302 exhibits a greater degree of the photoelectric effect at the wavelength of the EUV radiation than the base layer 301 or a typical patterning device.

The coating 302 may be formed of a variety of different materials. For example, the coating 302 may be formed of an alkali halide. In particular, caesium iodide (CsI) is shown to exhibit a high conversion efficiency of EUV photons into free electrons. Conversion efficiency is measured by measuring a current through a grounded surface irradiated by a light with known photon flux. Conversion efficiency is number of electrons produced per incident photon. Typically it is in the 1-10% level. Other non-limiting examples of alkali halides that can be used to form the coating 302 include caesium chloride (CsCl), rubidium chloride (RbCl), rubidium iodide (RbI) and barium chloride (BaCl). A more detailed discussion of the photoelectric effect of these materials may be found in Sharon R. Jelinsky, Oswald H. W. Siegmund, Jamil A. Mir, “Progress in soft x-ray and UV photocathodes”, Proc. SPIE 2808, EUV, X-Ray, and Gamma-Ray Instrumentation for Astronomy VII, (31 Oct. 1996); https://doi.org/10.1117/12.256036, which is hereby incorporated by reference in its entirety.

In addition to a higher conversion efficiency of EUV photons into free electrons, alkali halides may further exhibit a high secondary electron yield. That is, alkali halides may be able to capture a single electron and re-emit a larger number of free electrons. Forming the coating 302 of a material exhibiting high secondary electron yield may be advantageous because a greater electron flux may be generated.

In order to form the coating 302 from an alkali halide material, ion sputtering of a target of the same material target (as described in https://www.researchgate.net/publication/225388908_Ion-beam_sputtering_deposition_of_CsI_thin_f ilms) can be used. Alternatively a metal target (Cs, Rb) sputtering in a noble gas mixed with I2, Cl2 can produce a required film. After the coating 302 is initially formed, the coating 302 may be roughened as described above, or may be further processed to form grooves as described above. Alternatively or in addition, the surface of the base layer 301 may be roughened or have grooves formed before the coating 302 is applied.

As noted above, it may be desirable to have a degree of control over the direction of the electron flux generated by the coating 302 of the photoelectric plate 300. As explained above, because the average direction of the electron flux is generally perpendicular to the local normal of the surface of the coating 302, it is possible to control the direction of the electron flux by orientating the local surface of the coating 302 to the required angle.

However, as noted above, the direction of the electron flux is only an average direction. That is, in reality, the free electrons emitted from the coating 302 will have a distribution of directions of travel. In particular, in general, while the electrons of the greatest energy levels tend to be emitted in the direction perpendicular to the local surface, the electrons of the lowest energy levels tend to deviate the most form the direction perpendicular to the local surface. In order to concentrate more of the free electrons towards a direction of travel perpendicular to the local surface, the base layer 301 may be provided with a negative voltage bias.

For example, in the embodiment shown in FIG. 8, the photoelectric plate 300 may further comprise a voltage source 303 configured to apply a negative voltage bias to the base layer 301. As a result, relative to the grounded surfaces within the lithographic apparatus 100, the surface of the coating 302 may be at a more negative electric potential. As a result, electrons emitted from the coating 302 gain energy as they travel to the grounded (contaminated, non-critical) surfaces. As a result, the directions of travel of the emitted electrons may tend to concentrate more closely around the direction perpendicular to the local surface.

The negative voltage bias may be provided using different types of voltage source 303. For example, the voltage source 303 may be a direct current (DC) supply derived from mains electrical supply. Alternatively, the voltage source 303 may comprise a battery (not shown). In particular, the battery may be provided as part of the photoelectric plate 300. For example, the battery may be located within the base layer 301 of the photoelectric plate 300. In that case, a grounded connection of the patterning device support is used to close the circuit, the positive end of the integrated battery is grounded, utilizing the connections that normally are in contact with imaging reticle backside. An advantage of providing the negative voltage using a battery is that the photoelectric plate 300 may function as a standalone component without necessitating modifications or redesigning of existing lithographic apparatuses. That is, the photoelectric plate 300 may simply be provided alongside one or more patterning devices MA, and be attachable to the support structure MT in the same way as a patterning device MA.

In order to generate a negative electric potential, the base layer 301 may be formed of a dielectric material. For example, the base layer 301 may be formed of a low thermal expansion ceramic material, particularly non-conducting ceramics. For example, the base layer 301 may be formed of low thermal expansion glass. For example, the base layer 301 may be formed from the same material as the patterning device MA.

The photoelectric plate 300 described above may be provided together with a lithographic apparatus 100 in a lithographic system. In particular, the photoelectric plate 300 may be provided alongside one or more patterning devices MA as part of the lithography system. As noted above, the lithographic apparatus 90 may comprise a support structure MT for supporting a patterning device MA. The same support structure MT may also be used to support the photoelectric plate 300.

That is, the photoelectric plate 300 may be configured so as to be detachably attachable to the support structure MT. In other words, the photoelectric plate 300 may be clamped to the support structure MT in substantially the same way as a patterning device MA. As noted above, the support structure MT may use mechanical, vacuum, electrostatic or other clamping techniques to hold the patterning device MA. The support structure MT may use the same mechanical, vacuum, electrostatic or other clamping techniques to hold the photoelectric plate 300. Therefore, the side of the base layer 301 of the photoelectric plate 300 that is attachable to the support structure MT may have the same features as provided on the non-patterning surface 41 of the patterning device MA described above, for example a smooth and electrically-conducting coating.

Therefore, from a component interface point of view, the photoelectric plate 300 may be treated by the lithographic apparatus 100 as though it were one of the patterning devices MA. The photoelectric plate 300 may be treated as a “dummy” reticle. The photoelectric plate 300 may be provided with barcodes and/or other markers that enable the lithographic apparatus to “recognise” the photoelectric plate as a dummy reticle and to handle it accordingly, e.g. temporarily storing it within a reticle library in the lithographic apparatus and handling it with a standard reticle handler. Therefore, an existing lithographic apparatus 100 may be able to operate with the photoelectric plate 300 without requiring hardware modifications.

Any modifications to an existing lithographic apparatus 100 may be restricted to the software loaded onto the controller 500. Specifically, the controller 500 may be programmed to include a cleaning operation and any necessary steps for transitioning into and out of the cleaning operation. During the cleaning operation, when the photoelectric plate 300 is attached to the support structure MT, the lithographic apparatus 100 may direct EUV radiation 21 onto the photoelectric plate 300. The lithographic apparatus 100 may direct EUV radiation 21 onto the photoelectric plate 300 in substantially the same way as it directs EUV radiation 21 onto a patterning device MA during a lithography process. Specifically, the EUV radiation 21 used for the cleaning operation and the EUV radiation 21 used for a lithography process may come from the same EUV radiation source.

As noted above, an advantage of the present invention is that hardware modifications to existing lithographic apparatuses may not be necessary in order to incorporate a cleaning operation using the photoelectric plate 300 disclosed herein. In effect, whereas in known lithographic apparatuses the EUV radiation source is used to provide EUV radiation for patterning only, with the present invention, the same EUV radiation source may serve an additional purpose of providing radiation for the cleaning operation.

As discussed above with reference to FIG. 7, the coating 302 of the photoelectric plate 300 may be formed with a plurality of grooves formed by a plurality of surface segments 3022. As discussed above, the orientation of the plurality of surface segments 3022 may be selected to direct the free electrons in the required direction. A further factor that may influence the choice of the orientation of the surface segments 3022 of the coating 302 may include the angle of incidence of the EUV radiation.

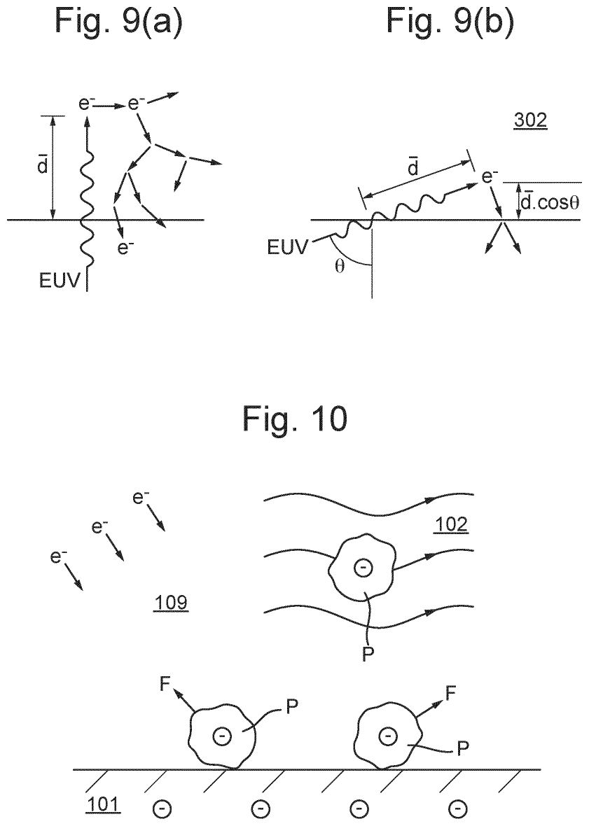

As shown in FIG. 9a, an EUV photon arrives at the surface of the coating 302 at a substantially perpendicular direction. As shown, the EUV photon may penetrate into the material of the coating 302 by a certain distance. The distance of penetration is, of course, random. Nevertheless, as shown in FIG. 9a, a statistical average of the penetration distance is denoted by d. As shown in FIG. 9a, when the EUV photon has reached an average distance of d, it interacts with an orbital electron and causes the electron to be released from the atom as a primary electron.

Because of the direction of the electromagnetic field of the EUV photon, the primary electron will have an initial direction of travel perpendicular to the direction of travel of the EUV photon. Afterwards, the primary electron scatters elastically and non-elastically with the nuclei and electrons of the coating 302, which causes the emission of one or more secondary electrons. The secondary electrons will have random directions of travel. The secondary electrons will generally encounter further atoms and generate further secondary electrons. As shown, some of the secondary electrons will eventually reach the surface of the coating 302 and escape from the coating 302, but only after several repetitions of the secondary electron generation process. However, in each inelastic scattering event, the energy of the product electrons is smaller than the energy of the scattering electron. As a result, the deeper into the coating 302 the photon penetrates, the lower is the energy level of the electrons that are emitted from the surface of the coating 302. As a further result, the free electrons emitted from the surface 302 may exhibit a large spread of directions of travel. Even though the average direction of travel of the emitted electrons would still be perpendicular to the local surface of the coating 302, the spread may be wider and the directionality may be poor.

It may be possible to improve the directionality by arranging the EUV photons to be incident on the surface of the coating 302 at an angle θ as shown in FIG. 9b. The EUV photon will still penetrate into the coating material by an average distance of d̅ as in the case where the EUV photon is incident on the coating surface at right angle. However, because the EUV photon enters the coating 302 at an angle of incidence θ, the point at which the EUV photon encounters an orbital electron will, on average, have a smaller perpendicular distance to the surface of the coating 302. More precisely, the average normal distance at which primary electrons are generated may be reduced to d̅. cos θ. As such, the shallower the angle of incidence of the EUV photon is (i.e. when θ is greater), the closer to the surface of the coating 302 will primary electrons be generated.

An effect the follows from a shallower angle of incidence is that the electrons may undergo fewer steps of re-capturing and re-generation before escaping the surface of the coating 302. As such, the flux of electrons emitted from the coating 302 may have a higher energy level and may exhibit improved directionality.

Therefore, by appropriately orientating the plurality of surface segments 3022 of the grooves of the coating 302, the EUV radiation may be arranged to be incident on the surface segments 3022 at an appropriate angle. For example, the EUV radiation may be incident on the surface segments 3022 at an angle of at least (i.e. no less shallow than) 45° to the local normal. Preferably, the angle of incidence θ of the EUV radiation may be at least 50°, at least 60°, at least 70°, at least 80°, or at least 85° to the local normal to the plurality of surface segments 3022 of the coating 302. Preferably, the EUV radiation may be incident on the surface segments 3022 at a grazing angle.

As noted above, during the lithography process, the support structure MT and its surroundings may be held in a partial vacuum environment. When EUV radiation is being directed onto the photoelectric plate 300 (i.e. during a cleaning operation), the support structure MT may continue to be held in a partial vacuum environment. This may be advantageous because the lithographic apparatus 100 may be maintained under partial vacuum throughout the cleaning operation. The pressure during the cleaning operation may be lower than the pressure during an exposure process, e.g. in the range of from about 1 to 10 Pa. As a result, following the cleaning operation, the lithographic apparatus 100 may be quickly brought back to the ready-for-exposure state, ready for the next lithography operation.

In contrast with the prior-art flushing technique mentioned above, which requires raising the gas pressure within the patterning device environment 90 and therefore bringing the lithographic apparatus 100 out of the ready-for-exposure state, the ability to perform a cleaning operation whilst maintaining the partial vacuum may increase the productive availability of the lithographic apparatus 100.

The operation principles of the cleaning operation will now be explained with reference to FIG. 10. As shown, a number of contaminants P are adhered to a surface 101 of the lithographic apparatus 100. A flux of free electrons is directed towards the surface 101 and the contaminant particles P. The flux of free electrons is generated using the photoelectric plate 300 as described above. As the free electrons arrive at the surface 101 of the lithographic apparatus 100 and the contaminants particles P, the surface 101 and the contaminant particles P become negatively charged. Due to the negative charges on the contaminant particles P and the surface 101, the contaminant particles P may be repelled away from each other and away from the surface 101, as indicated by repulsion forces F. The repulsion forces acting on the contaminant particles P may cause the contaminant particles P to be lifted off the surface 101. Therefore, the surface 101 is cleaned.

In order to remove the released contaminant particles P from the lithographic apparatus 100, the lithographic apparatus 100 may be further configured to provide a gas flow 102 through the partial vacuum environment 109. As shown in FIG. 10, any released contaminant particles P may be carried by the gas flow 102 away from the surface 101, until they are sucked away from the lithographic apparatus 100 through an exit to the partial vacuum environment 109.

A further cleaning technique could be combined with the generation of an electron flux using the photoelectric plate 300 as described above. The partial vacuum environment 109 may be filled with a low pressure of hydrogen gas. It has been found that contaminant particles P are more likely to be released when the gas pressure is reduced. Therefore, in order to enhance the cleaning effect provided by the flux of free electrons, the gas pressure within the partial vacuum environment may be further lowered during the cleaning operation. More specifically, the lithographic apparatus 100 may be configured to maintain the partial vacuum environment at a first pressure during a lithographic patterning process, and the lithographic apparatus may be further configured to maintain the partial vacuum environment 109 at a second pressure lower than the first pressure when directing EUV radiation onto the photoelectric plate 300. In other words, during a cleaning operation, the lithographic apparatus 100 may be configured to operate at a lower gas pressure than during a lithographic patterning process.

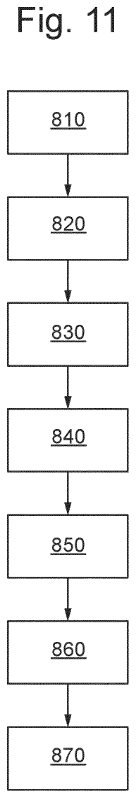

FIG. 11 shows a possible transition into and out of a cleaning operation. As shown, at step 801, the lithographic apparatus 100 is initially in the ready-for-exposure state, meaning that the apparatus provide the conditions necessary for a lithographic patterning process. This may include maintaining the partial vacuum environment 109 at the first pressure.

Next, at steps 820 and 830 respectively, the photoelectric plate 300 is attached to the support structure MT and the gas pressure within the partial vacuum environment 109 is reduced to a second pressure lower than the first pressure. Steps 820 and 830 may take place in the order shown in FIG. 11, or may take place in the opposite order. Steps 820 and 830 may also take place simultaneously. Steps 820 and 830 may also overlap in time.

Next, at step 840, EUV radiation may be directed onto the photoelectric plate 300, now attached to the support structure MT. The cleaning operation may therefore begin. The cleaning operation may be maintained for a certain time (e.g. about 10 to 100 minutes, a suitable time may be determined experimentally), during which time a EUV radiation is continually directed onto the photoelectric plate 300. Also, during this time, free electrons are generated by the coating 302 provided on the photoelectric plate 300, which free electrons may be directed to different surfaces of the lithographic apparatus 100 as required, as explained above. The coating 302 may be kept grounded, or negatively biased during cleaning, with typical voltage in the range of from about −10 V to about −100 V.

Next, at steps 850 and 860 respectively, the pressure within the partial vacuum environment 109 may be brought back to the first pressure, and the photoelectric plate 300 may be detached from the support structure MT. Steps 850 and 860 may be performed in either order, or simultaneously. Steps 850 and 860 may also overlap in time.

When the photoelectric plate 300 is detached and the pressure within the partial vacuum environment is brought back up to the first pressure, the lithographic apparatus 100 is once again in the ready-for-exposure state (step 870). The lithographic apparatus 100 may therefore return to the lithographic patterning process.

Although the above disclosure mentions providing a photoelectric plate 300 with the lithographic apparatus 100, several photoelectric plates 300 may be provided. Each of the photoelectric plates 300 may be configured to direct free electrons to different surfaces of the lithographic apparatus 100. For example, the photoelectric plates 300 may have different groove patterns which preferentially direct free electrons towards different surfaces of the lithographic apparatus 100.

Where a plurality of photoelectric plates 300 is provided, an appropriate one of the photoelectric plates 300 may be used during a cleaning operation. The lithographic apparatus 100 may be configured to use a different photoelectric plate 300 each time it enters the cleaning operation. Additionally or alternatively, the lithographic apparatus may be configured to use several photoelectric plates 300 during a single cleaning operation. For example, the cleaning operation at step 840 may be divided into two or more phases in which different photoelectric plates 300 are used.

For example, the cleaning operation may begin with a first photoelectric plate 300 attached to the support structure MT. After a certain time, the lithographic apparatus 100 may temporarily pause the direction of EUV radiation onto the first photoelectric plate 300, swap the first photoelectric plate for a second photoelectric plate 300, and then resume directing EUV radiation towards the second photoelectric plate 300. Whilst the photoelectric plates 300 are being swapped, the partial vacuum environment may be maintained at the second, lower, gas pressure, so as not to lengthen the cleaning operation.

As noted above, alternatively or in addition, a photoelectric plate may have parts configured to direct free electrons to different surfaces of the lithographic apparatus 100. For example, the photoelectric plate 300 may have parts or regions with different groove patterns which preferentially direct free electrons towards different surfaces of the lithographic apparatus 100. For example, a photoelectric plate may have a first part that preferentially directs electrons towards a first surface of the lithographic apparatus 100 and a second part that preferentially directs electrons towards a second surface of the lithographic apparatus 100. The photoelectric plate may be positioned by the first positioner PM during the cleaning operation so that the EUV radiation is incident on different parts of the photoelectric plate 300 at different times during the cleaning operation to preferentially direct free electrons towards different surfaces of the lithographic apparatus 100.

Although specific reference may be made in this text to the use of a lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Where the context allows, embodiments of the invention may be implemented in hardware, firmware, software, or any combination thereof. Embodiments of the invention may also be implemented by instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic storage media; optical storage media; flash memory devices; electrical, optical, acoustical or other forms of propagated signals (e.g. carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc. and in doing that may cause actuators or other devices to interact with the physical world.

Although specific reference may be made in this text to embodiments of the invention in the context of a lithographic apparatus, embodiments of the invention may be used in other apparatus. Embodiments of the invention may form part of a mask inspection apparatus, a metrology apparatus, or any apparatus that measures or processes an object such as a wafer (or other substrate) or mask (or other patterning device). These apparatus may be generally referred to as lithographic tools.

Although specific reference may have been made above to the use of embodiments of the invention in the context of optical lithography, it will be appreciated that the invention, where the context allows, is not limited to optical lithography.

Aspects of the invention are described in the following numbered clauses.
1. A photoelectric plate (300) for use in place of a patterning device in a lithographic apparatus, the photoelectric plate comprising:
a base layer (301); and
a coating (302) provided on the base layer;
wherein the coating is configured to convert impinging photons of EUV radiation into free electrons at a higher conversion efficiency than the base layer.
2. The photoelectric plate of clause 1, wherein a surface (3021) of the coating has a roughness configured cause the free electrons to be emitted as a diffuse electron flux.
3. The photoelectric plate of clause 1, wherein the coating is formed with a plurality of grooves.
4. The photoelectric plate of clause 3, wherein the plurality of grooves are formed by a plurality of surface segments (3022), and the surface segments are non-parallel to the base layer.
5. The photoelectric plate of clause 4, wherein the surface segments are at an angle of to 50 degrees to the base layer, optionally at 45 degrees to the base layer.
6. The photoelectric plate of any one of clauses 3 to 5, wherein the grooves have a width(s) greater than 1 um.
7. The photo electric plate of any one of clauses 3 to 6, wherein the coating comprises first and second parts, and each of the first and second part of the coating is formed with a different plurality of grooves configured to direct free electrons in a different direction.
8. The photoelectric plate of any one of the preceding clauses, wherein the coating is formed of an alkali halide.
9. The photoelectric plate of clause 8, wherein the coating comprises Caesium, Rubidium, Iodine, Chlorine, Bromine or compounds thereof.
10. The photoelectric plate of any one of the preceding clauses, configured to apply negative bias up to 100 V to the coating (302) using external or internal voltage source.
11. The photoelectric plate of clause 10, wherein the internal voltage source comprises a battery.
12. The photoelectric plate of any one of the preceding clauses, wherein the base layer comprises a dielectric material, e.g. a low expansion ceramic or glass, and optionally a conductive coating on the side opposite of the coating (302), that enables electrostatic clamping.
13. A lithography system comprising a lithographic apparatus (100) and the photoelectric plate of any one of the preceding clauses.
14. The lithography system of clause 13, wherein the photoelectric plate is detachably attachable to a support structure (MT) for supporting a patterning device.
15. The lithography system of clause 14, wherein the support structure (MT) is configured to provide a grounding and/or negative voltage to the coating (302) directly or via backside conducting coating of the base layer (301).
16. The lithography system of clause 13, 14 or 15, wherein the lithographic apparatus is configured to direct EUV radiation (21) onto the photoelectric plate when the photoelectric plate is attached to the support structure.
17. The lithography system of clause 16, wherein the coating of the photoelectric plate is formed with a plurality of grooves formed by a plurality of surface segments, and the surface segments are oriented so that, when the photoelectric plate is attached to the support structure, EUV radiation is incident on the surface segments at an angle (θ) of at least 45 degrees to the local normal.
18. The lithography system of clause 16 or 17, wherein the support structure is held in a partial vacuum environment (109) when EUV radiation is directed to the photoelectric plate.
19. The lithography system of clause 18, wherein the lithographic apparatus is configured to provide a gas flow (102) through the partial vacuum environment.
20. The lithography system of clause 18 or 19, wherein the lithographic apparatus is configured to maintain the partial vacuum environment at a first pressure during a lithographic patterning process, and to maintain the partial vacuum environment at a second pressure lower than the first pressure when directing EUV radiation onto the photoelectric plate.
21. A method comprising:
   placing the photoelectric plate of any one of clauses 1 to 12 in a patterning device support structure (MT) of a lithographic apparatus (100); and
   directing EUV radiation (21) onto the photoelectric plate.
22. The method of clause 21, wherein the coating of the photoelectric plate is formed with a plurality of grooves formed by a plurality of surface segments (3022), and the surface segments are oriented so that the EUV radiation is incident on the surface segments at an angle of at least 45 degrees to the local normal.
23. The method of clause 21 or 22, further comprising holding the support structure in a vacuum environment (109) of the lithographic apparatus when directing EUV radiation to the photoelectric plate.
24. The method of clause 23, further comprising providing a gas flow (102) through
the partial vacuum environment.
25. The method of clause 23 or 24, wherein the lithographic apparatus is configured to maintain the partial vacuum environment at a first pressure during a lithographic patterning process, and the method further comprises maintaining the partial vacuum environment at a second pressure lower than the first pressure when directing EUV radiation onto the photoelectric plate.
26. The method of any of clauses 21 to 25, wherein the coating (302) is grounded or negatively biased, e.g. at a potential of up to −100 V, during the step of directing EUV radiation.
27. The method of any of clauses 21 to 26, wherein the pressure near the photoelectric plate during the step of directing EUV radiation is same or smaller than the pressure during an exposure process, e.g. 1 to 10 Pa or less.

While specific embodiments of the invention have been described above, it will be appreciated that the invention may be practiced otherwise than as described.

The descriptions above are intended to be illustrative, not limiting. Thus, it will be apparent to one skilled in the art that modifications may be made to the invention as described without departing from the scope of the claims set out below.

1.-27. (canceled)

28. A photoelectric plate for use in place of a patterning device in a lithographic apparatus, the photoelectric plate comprising:
a base layer having a conversion efficiency; and
a coating disposed on the base layer;
wherein the coating is configured to convert impinging photons of extreme ultraviolet (EUV) radiation into free electrons at a higher conversion efficiency than the conversion efficiency of the base layer.

29. The photoelectric plate of claim 28, wherein a surface of the coating has a roughness configured to cause the free electrons to be emitted as a diffuse electron flux.

30. The photoelectric plate of claim 28, wherein the coating comprises a plurality of grooves.

31. The photoelectric plate of claim 30, wherein the plurality of grooves have a plurality of surface segments, and the surface segments are non-parallel to the base layer.

32. The photoelectric plate of claim 28, wherein the coating comprises an alkali halide.

33. The photoelectric plate of claim 32, wherein the coating comprises Caesium, Rubidium, Iodine, Chlorine, Bromine or compounds thereof.

34. The photoelectric plate of claim 28, further configured to receive application of a negative bias of up to 100 V to the coating by a voltage source.

35. The photoelectric plate of claim 28, wherein the base layer comprises a dielectric material or a low expansion ceramic or glass.

36. A lithography system comprising a lithographic apparatus and the photoelectric plate of claim 28.

37. The lithography system of claim 36, wherein the photoelectric plate is detachably attachable to a support structure that supports a patterning device.

38. The lithography system of claim 37, wherein the support structure is configured to provide a grounding and/or negative voltage to the coating directly or via backside conducting coating of the base layer.

39. The lithography system of claim 37, wherein the lithographic apparatus is configured to direct EUV radiation onto the photoelectric plate when the photoelectric plate is attached to the support structure.

40. The lithography system of claim 39, wherein the coating of the photoelectric plate comprises a plurality of grooves having a plurality of surface segments, and the surface segments are oriented so that, when the photoelectric plate is attached to the support structure, EUV radiation is incident on the surface segments at an angle (θ) of at least 45 degrees to a local normal.

41. A method comprising:
placing the photoelectric plate of claim 28 in a patterning device support structure of a lithographic apparatus; and
directing EUV radiation onto the photoelectric plate.

42. The method of claim 41, wherein the coating of the photoelectric plate comprises a plurality of grooves having a plurality of surface segments, and the surface segments are oriented so that the EUV radiation is incident on the surface segments at an angle of at least 45 degrees to a local normal.

43. The photoelectric plate of claim 35, further comprising a conductive coating on a side opposite of the coating that enables electrostatic clamping of the photoelectric plate.
